(19) United States
(12) Patent Application Publication
(10) Pub. No.: US 2026/0323220 A1
(43) Pub. Date: Oct. 15, 2026

(54) ACOUSTIC TRANSDUCER AND ELECTRONIC DEVICE

(71) Applicant: GOERTEK INC., Weifang (CN)

(72) Inventors: Xiaodong CAI, Weifang (CN); Song LIU, Weifang (CN)

(21) Appl. No.: 19/693,903

(22) Filed: Jun. 1, 2026

Related U.S. Application Data
(63) Continuation of application No. PCT/CN2025/105399, filed on Jun. 30, 2025.

(30) Foreign Application Priority Data
Oct. 25, 2024 (CN) 202411505094.8

(51) Int. Cl. H04R 9/02; H04R 1/02; H04R 1/06; H04R 7/12; H04R 9/04; H04R 9/06; H05K 5/02

(52) U.S. Cl. CPC H04R 9/025; H04R 1/023; H04R 1/025; H04R 1/06; H04R 7/127; H04R 9/045; H04R 9/06; H05K 5/0215

(57) ABSTRACT

An acoustic transducer includes a housing; a magnetic circuit system; and a vibration system. The magnetic circuit system includes a support plate and two magnet assemblies provided at the support plate at intervals. A magnetic gap is formed between the two magnet assemblies. The support plate is made of a non-magnetic material. Each magnet assembly includes a first magnet, a second magnet and a third magnet provided sequentially along a first direction. The third magnet is provided at the support plate, the first magnet and the third magnet are magnetized along a second direction, and magnetization directions of the first magnet and the third magnet are opposite. The first direction is perpendicular to the second direction. The vibration system includes a diaphragm and a flat voice coil configured to drive the diaphragm to vibrate along the first direction.

### CROSS-REFERENCE TO RELATED APPLICATIONS

This application is a continuation application of International Application No. PCT/CN2025/105399, filed on Jun. 30, 2025, which claims priority to Chinese Patent Application No. 202411505094.8, filed on Oct. 25, 2024. The disclosures of the above-mentioned applications are incorporated herein by reference in their entireties.

### TECHNICAL FIELD

The present application relates to the technical field of acoustic energy conversion, and in particular to an acoustic transducer and an electronic device.

### BACKGROUND

With the trend toward lighter and thinner smart wearable products, for acoustic transducers, the mounting space available for speakers is gradually decreasing without changing the mounting space of other components. The acoustic performance of a speaker is positively correlated with the volume of the speaker. As the mounting space for speakers is continuously compressed, it is difficult to increase the volume of the speaker, making it difficult to improve the acoustic performance of the speaker and unable to meet user requirements.

### SUMMARY

The main purpose of the present application is to provide an acoustic transducer and an electronic device, aiming to improve the acoustic performance of a speaker.

To achieve the above purpose, the present application provides an acoustic transducer, a aspect ratio of the acoustic transducer being greater than 2:1, the acoustic transducer includes:
a housing;
a magnetic circuit system; and
a vibration system,
the magnetic circuit system includes a support plate and two magnet assemblies provided at the support plate at intervals, and a magnetic gap is formed between the two magnet assemblies; the support plate is made of a non-magnetic material, and each magnet assembly includes a first magnet, a second magnet and a third magnet provided sequentially along a first direction; the third magnet is provided at the support plate, and the first magnet and the third magnet are magnetized along a second direction; magnetization directions of the first magnet and the third magnet are opposite, and the first direction is perpendicular to the second direction;
the second magnet is magnetized along the first direction, and a polarity of a magnetic pole of the second magnet facing the first magnet is the same as a polarity of a magnetic pole of the first magnet adjacent to the magnetic gap, to make each magnet assembly form a magnetic field enhancement side facing the magnetic gap; the polarities of the magnetic poles of the two first magnets adjacent to the magnetic gap are opposite; and
the vibration system includes a diaphragm and a flat voice coil configured to drive the diaphragm to vibrate along the first direction, and the diaphragm includes a folded ring and a reinforcement part provided in a central area of the folded ring; the folded ring is connected to the housing, and the flat voice coil is connected to the reinforcement part and located in the magnetic gap; and an axial direction of the flat voice coil is provided along the second direction.

In an embodiment, the acoustic transducer further includes:
a waterproof seal ring,
the waterproof seal ring is provided around the folded ring; the waterproof seal ring, the folded ring, the reinforcement part and the housing are integrally injection-molded; or
an outer side wall of the waterproof seal ring is provided with a first inclined surface provided obliquely inwards; an inner side wall of the waterproof seal ring is provided with a second inclined surface provided obliquely outwards; and an included angle between the first inclined surface and the first direction is greater than an included angle between the second inclined surface and the first direction.

In an embodiment, the vibration system further includes a bracket, and the reinforcement part and the flat voice coil are connected to the bracket; or
the reinforcement part is provided with a bent support part extended along the first direction, and the support part is connected to the flat voice coil; and/or
the vibration system further includes a reinforcement bracket; the reinforcement bracket is provided at a side of the reinforcement part facing the flat voice coil, and the reinforcement bracket is bent towards the flat voice coil along the first direction to form a reinforcement bent part; a ratio of a height of the reinforcement bent part in the first direction to a width of the reinforcement part in the second direction is greater than 1:4; or
the ratio of the height of the reinforcement bent part in the first direction to the width of the reinforcement part in the second direction is not less than 1:10, and not greater than 1:4.

In an embodiment, the reinforcement part is provided with a plurality of micro holes, and the acoustic transducer further includes a waterproof and breathable film covering the micro holes; or
at least a part of a structure of the reinforcement part is made of a breathable material, and the acoustic transducer further includes a waterproof and breathable film covering the breathable material; and/or
the reinforcement part is provided with reinforcing ribs, and the reinforcing ribs are located in a central area of the reinforcement part and extend along a long side direction of the housing.

In an embodiment, the housing includes an annular main body and a side wall connected to the annular main body; the side wall is provided with a first through hole, and the magnet assembly is provided with a first protruding part extending into the first through hole; and/or
a side of the first magnet adjacent to the magnetic gap protrudes distant from the support plate along the first direction to form a second protruding part; the housing is provided with a second through hole configured to avoid the second protruding part, and the second through hole is communicated with the magnetic gap.

In an embodiment, the acoustic transducer includes:
a centering plate,
the centering plate includes a first fixation part, an elastic arm part and a second fixation part; the first fixation part is provided at the housing, and the second fixation part is connected to the flat voice coil; one end of the elastic arm part is connected to the first fixation part, and the other end of the elastic arm part is connected to the second fixation part.

In an embodiment, two centering plates are provided; one of the two centering plates is provided at one end of the housing along a long side direction, and the other of the two centering plates is provided at the other end of the housing along the long side direction; the two centering plates are connected by a conductive connecting part, and the conductive connecting part is provided with an external welding pad electrically connected to an external circuit.

In an embodiment, the housing includes an annular main body and a side wall connected to the annular main body, and the support plate includes a bottom plate and a coaming; the magnet assembly is provided at the bottom plate, and the coaming is connected to the side wall; and the first fixation part is clamped between the coaming and the side wall; and/or
the first fixation part is provided with a glue injection hole, and the housing is provided with a glue injection groove communicated with the glue injection hole; and the glue injection groove is configured to contain glue; and/or
the first fixation part is provided with a first welding pad, and the housing is provided with a second welding pad welded with the first welding pad; and/or
the vibration system further includes a bracket; the bracket includes a main body part, a first connecting part, a second connecting part, and a third connecting part; the main body part extends along the first direction; the first connecting part is located at one end of the main body part along the first direction, and the second connecting part is located at the other end of the main body part along the first direction; the first connecting part and the second connecting part are bent along the second direction, and the third connecting part extends from an inner edge of the main body part along the first direction; the first connecting part is connected to the reinforcement part; the second connecting part is connected to the second fixation part; and the third connecting part is connected to a side surface of the flat voice coil.

In an embodiment, the conductive connecting part and the centering plate are an integrally molded part; the conductive connecting part includes a main body part and an external connecting part; the main body part is connected to the two centering plates, and the external connecting part is connected to one end of the main body part; the external connecting part is provided with the external welding pad, and the main body part is provided at a side surface of the magnetic circuit system; and/or
an outer surface of the main body part is within a range of an outer surface of the housing; and/or
the acoustic transducer further includes a pressing plate, and the pressing plate is connected to the housing; the main body part is provided between the third magnet and the pressing plate, and an outer surface of the pressing plate is within a range of the outer surface of the housing.

In an embodiment, the acoustic transducer further includes:
a front cover; and
a dustproof net,
the front cover is provided at a side of the diaphragm distant from the magnetic circuit system; the front cover is provided with mesh holes, and the dustproof net covers the mesh holes.

In an embodiment, the acoustic transducer further includes:
a waterproof seal ring,
the waterproof seal ring is connected to a side of the housing distant from the magnetic circuit system, and the waterproof seal ring surrounds the folded ring and forms an annular step at a joint of the waterproof seal ring and the folded ring; the front cover is provided at the annular step and located inside the waterproof seal ring; and/or
the mesh holes are of an irregular shape; and/or
the mesh holes include first holes and second holes, and hole areas the first holes and the second holes are different; the first holes and the second holes are staggered along a long side or a short side of the acoustic transducer, or the first holes are scattered between the second holes, or the front cover includes a first area corresponding to the first holes and a second area corresponding to the second holes.

In an embodiment, the flat voice coil includes a first long-axis section and a second long-axis section, and the first long-axis section and the second long-axis section are provided at intervals sequentially along the first direction; the first long-axis section is connected to the diaphragm, and the first long-axis section and the second long-axis section extend along a third direction; the first direction, the second direction and the third direction are mutually orthogonal;
a thickness of the first magnet along the first direction is not less than 80 percent of a height of the first long-axis section along the first direction; and/or
a thickness of the third magnet along the first direction is not less than 80 percent of a height of the second long-axis section along the first direction; and/or
a thicknesses of the first magnet and the third magnet along the first direction are greater than a thickness of the second magnet along the first direction.

In an embodiment, an aspect ratio of an inner diameter of the flat voice coil is not greater than 20:1; and/or
the aspect ratio of the acoustic transducer is not greater than 10:1; and/or
the housing includes a central part and two end parts; one of the two end parts is located at one end of the central part along the long side direction of the housing, and the other one of the two end parts is located at the other end of the central part along the long side direction of the housing; and an outer surface of the central part protrudes towards a side distant from the flat voice coil.

In an embodiment, the support plate is provided with an avoiding groove configured to avoid the flat voice coil; or
the support plate is provided with an avoiding hole configured to avoid the flat voice coil; the acoustic transducer further includes a covering part covering the avoiding hole, and the covering part is provided at a side of the support plate distant from the magnet assembly along the first direction; and/or
the support plate includes a bottom plate, a coaming provided at a periphery of the bottom plate, and a first mounting lug and a second mounting lug; the first mounting lug is provided at one end of the coaming along the third direction, and the second mounting lug is provided at the other end of the coaming along the third direction; the first mounting lug is provided with a first mounting hole and a first positioning hole at intervals along the third direction, and the second mounting lug is provided with a second mounting hole and a second positioning hole at intervals along the third direction; the second positioning hole extends through an outer edge of the second mounting lug along the third direction, and the first direction, the second direction and the third direction are mutually orthogonal.

The present application further provides an electronic device, the electronic device includes a shell and the acoustic transducer described as above, the acoustic transducer is provided in the shell.

In the technical solution of the present application, two magnet assemblies are provided at intervals, each magnet assembly is formed by stacking a first magnet, a second magnet and a third magnet along a first direction, the first magnet and the third magnet are magnetized along a second direction, and magnetization directions of the first magnet and the third magnet are opposite, the second magnet is magnetized along the first direction, and the polarity of the magnetic pole of the second magnet facing the first magnet is the same as the polarity of the magnetic pole of the first magnet adjacent to the magnetic gap, so that each magnet assembly can form a magnetic field enhancement side facing the magnetic gap, thereby improving the magnetic force and the acoustic performance of the speaker.

### BRIEF DESCRIPTION OF THE DRAWINGS

To more clearly illustrate the embodiments of the present application or the technical solutions in the related art, the drawings required for the description of the embodiments or the related art will be briefly introduced below. Obviously, the drawings described below are only some embodiments of the present application, and for those skilled in the art, other drawings can be obtained according to the structures shown in these drawings without creative effort.

FIG. 1 is a structural schematic view of an acoustic transducer according to an embodiment of the present application.

FIG. 2 is an exploded structural schematic view of the acoustic transducer according to an embodiment of the present application.

FIG. 3 is a sectional structural schematic view of the acoustic transducer according to an embodiment of the present application.

FIG. 4 is a partially enlarged schematic view at portion A in FIG. 3.

FIG. 5 is a partial structural schematic view of the acoustic transducer according to an embodiment of the present application.

FIG. 6 is a partial structural schematic view of the acoustic transducer from a perspective according to an embodiment of the present application.

FIG. 7 is a structural schematic view of a diaphragm and a housing according to an embodiment of the present application.

FIG. 8 is a sectional structural schematic view of a reinforcement part and a reinforcement bracket according to an embodiment of the present application.

FIG. 9 is a structural schematic view of the reinforcement part and the reinforcement bracket according to an embodiment of the present application.

FIG. 10 is a structural schematic view of the reinforcement part and the reinforcement bracket according to an embodiment of the present application.

FIG. 11 is a structural schematic view of a magnet assembly and a flat voice coil according to an embodiment of the present application.

FIG. 12 is a schematic view of a distribution of magnetic field lines the magnet assembly and the flat voice coil according to an embodiment of the present application.

FIG. 13 is a structural schematic view of a centering plate and the housing according to an embodiment of the present application.

FIG. 14 is a structural schematic view of a support plate according to an embodiment of the present application.

FIG. 15 is a structural schematic view of the reinforcement part provided with reinforcing ribs according to an embodiment of the present application.

FIG. 16 is a structural schematic view of the acoustic transducer according to an embodiment of the present application.

FIG. 17 is a structural schematic view of a front cover provided with first holes and second holes according to an embodiment of the present application.

FIG. 18 is a structural schematic view of the front cover according to an embodiment of the present application.

FIG. 19 is a structural schematic view of the front cover provided with first holes and second holes according to an embodiment of the present application.

FIG. 20 is a structural schematic view of the front cover according to an embodiment of the present application.

FIG. 21 is a structural schematic view of the front cover according to an embodiment of the present application.

FIG. 22 is a structural schematic view of the front cover provided with first holes and second holes according to an embodiment of the present application.

FIG. 23 is a structural schematic view of the acoustic transducer provided in a shell according to an embodiment of the present application.

The realization, functional features and advantages of the present application will be further described with reference to the embodiments and the accompanying drawings.

### DETAILED DESCRIPTION OF THE EMBODIMENTS

The technical solutions in the embodiments of the present application will be clearly and completely described below with reference to the accompanying drawings in the embodiments of the present application. Obviously, the described embodiments are only a part of the embodiments of the present application, rather than all the embodiments. Based on the embodiments of the present application, all other embodiments obtained by those skilled in the art without creative effort are within the protection scope of the present application.

It should be noted that if the embodiments of the present application involve directional indications (such as up, down, left, right, front, rear, etc.), the directional indications are only used to explain the relative positional relationship, movement situation, etc. between the components under a specific posture. If the specific posture changes, the directional indications will also change accordingly.

In addition, if the embodiments of the present application involve descriptions such as “first”, “second”, etc., the descriptions of “first”, “second”, etc. are only for descriptive purposes, and cannot be understood as indicating or implying their relative importance or implicitly specifying the number of indicated technical features. Thus, the features defined with “first” or “second” may explicitly or implicitly include at least one of the features. In addition, the “and/or” appearing in the whole text includes three parallel schemes. Taking “A and/or B” as an example, it includes scheme A, scheme B, or a scheme where A and B are satisfied at the same time. In addition, the technical solutions of the various embodiments can be combined with each other, but it must be based on the realization by those skilled in the art. When the combination of technical solutions is contradictory or cannot be realized, it should be considered that such a combination of technical solutions does not exist and is not within the claimed protection scope of the present application.

With the trend toward lighter and thinner smart wearable products, for acoustic transducers, the mounting space available for speakers is gradually decreasing without changing the mounting space of other components. The acoustic performance of a speaker is positively correlated with the volume of the speaker. As the mounting space for speakers is continuously compressed, it is difficult to increase the volume of the speaker, making it difficult to improve the acoustic performance of the speaker and unable to meet user requirements.

In view of this, the present application provides an acoustic transducer and an electronic device, aiming to improve the acoustic performance of a speaker.

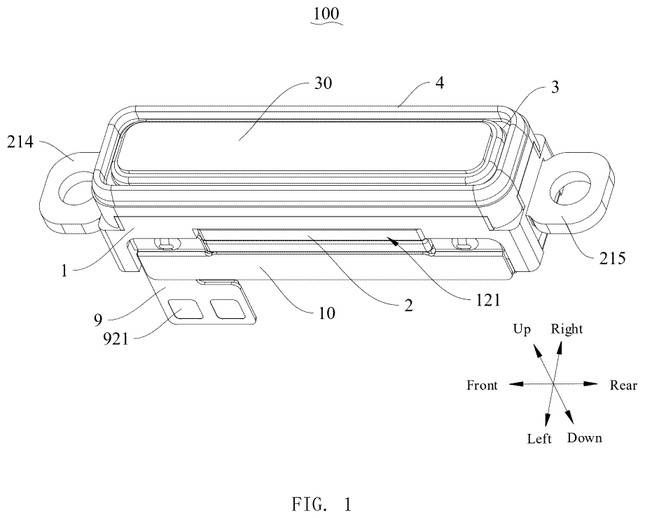

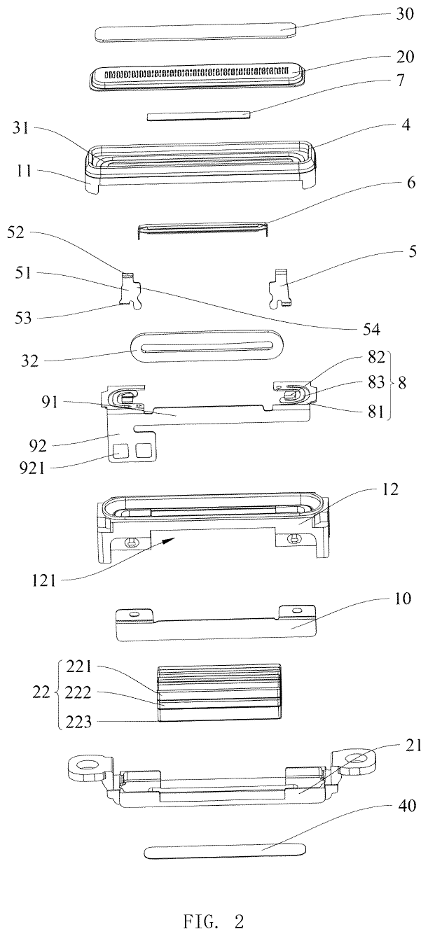

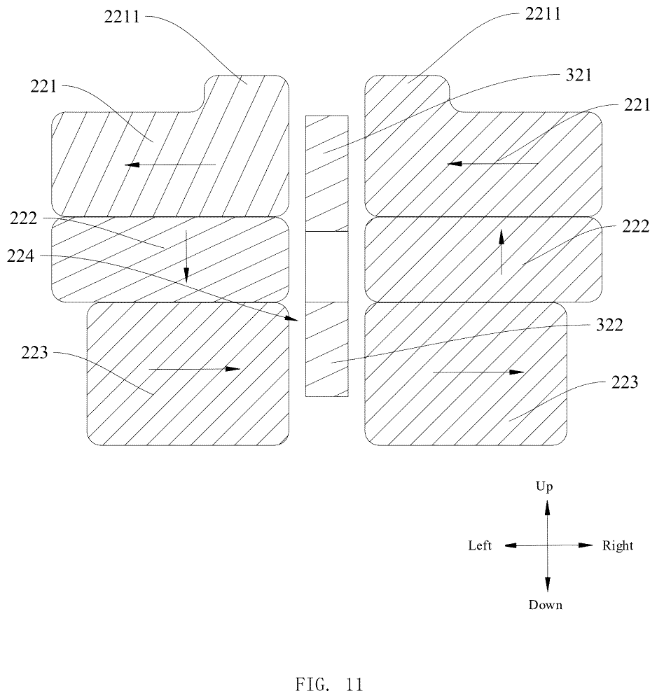

As shown in FIG. 1, FIG. 2, FIG. 11 and FIG. 12, in an embodiment the present application, the aspect ratio of the acoustic transducer 100 is greater than 2:1, the acoustic transducer 100 includes a housing 1, a magnetic circuit system 2 and a vibration system 3. The magnetic circuit system 2 includes a support plate 21 and two magnet assemblies 22 provided at the support plate 21 at intervals. A magnetic gap 224 is formed between the two magnet assemblies 22. The support plate 21 is made of a non-magnetic material. Each magnet assembly 22 includes a first magnet 221, a second magnet 222 and a third magnet 223 provided sequentially along a first direction. The third magnet 223 is connected to the support plate 21, the first magnet 221 and the third magnet 223 are magnetized along a second direction, and magnetization directions of the first magnet 221 and the third magnet 223 are opposite, the first direction is perpendicular to the second direction. The second magnet 222 is magnetized along the first direction, and the polarity of the magnetic pole of the second magnet 222 facing the first magnet 221 is the same as the polarity of the magnetic pole of the first magnet 221 adjacent to the magnetic gap 224, to make each magnet assembly 22 form a magnetic field enhancement side facing the magnetic gap 224, and the polarities of the magnetic poles of the two first magnets 221 adjacent to the magnetic gap 224 are opposite. The vibration system 3 includes a diaphragm 31 and a flat voice coil 32 configured to drive the diaphragm 31 to vibrate along the first direction. The diaphragm 31 includes a folded ring 311 and a reinforcement part 312 provided in a central area of the folded ring 311. The folded ring 311 is connected to the housing 1. The flat voice coil 32 is connected to the reinforcement part 312 and located in the magnetic gap 224, and the axial direction of the flat voice coil 32 is provided along the second direction.

The acoustic transducer 100 of the present application can be a speaker transducer, and the acoustic transducer 100 can be applied to an acoustic module of an electronic device, where the electronic device can be a computer, a mobile phone, an intelligent wearable device, etc. The present embodiment is described by taking the acoustic transducer 100 as a speaker transducer as an example.

In the technical solution of the present application, two magnet assemblies 22 are provided at intervals. Each magnet assembly 22 is formed by stacking a first magnet 221, a second magnet 222 and a third magnet 223 along a first direction. The first magnet 221 and the third magnet 223 are magnetized along a second direction, and magnetization directions of the first magnet 221 and the third magnet 223 are opposite. The second magnet 222 is magnetized along the first direction, and the polarity of the magnetic pole of the second magnet 222 facing the first magnet 221 is the same as the polarity of the magnetic pole of the first magnet 221 adjacent to the magnetic gap 224, so that each magnet assembly 22 can form a magnetic field enhancement side facing the magnetic gap 224. The polarities of the magnetic poles of the two first magnets 221 adjacent to the magnetic gap 224 are opposite, so that the magnetic field lines of the two magnet assemblies 22 form an annular shape, thereby improving the magnetic force and the acoustic performance of the speaker.

As shown in FIG. 1, the first direction is the up-down direction, and the second direction is the left-right direction. The first magnet 221 being magnetized leftwards is used as an example, the second magnet 222 located at the left side of the magnetic gap 224 is magnetized downwards, the second magnet 222 located at the right side of the magnetic gap 224 is magnetized upwards, and the third magnet 223 is magnetized rightwards, so that each magnet assembly 22 forms a magnetic field enhancement side facing the magnetic gap 224, and the two magnet assemblies 22 can form a complete closed loop of magnetic field lines, thereby improving the magnetic field strength and the acoustic performance of the speaker. It should be noted that the support plate 21 is made of a non-magnetic material to allow more magnetic field lines to pass through the flat voice coil 32 and avoid the dispersion of magnetic field lines.

In the present embodiment, the acoustic transducer 100 is narrow and long in shape. The acoustic transducer 100 has a height (thickness) along the first direction, and a length and a width along the direction perpendicular to the first direction. The aspect ratio of the acoustic transducer 100 is greater than 2:1, which can better adapt to the reserved space of micro electronic devices.

It should be noted that the aspect ratio of the acoustic transducer 100 refers to the ratio of the length of the acoustic transducer 100 along the third direction to the width of the acoustic transducer 100 along the second direction. The first direction, the second direction and the third direction are mutually orthogonal. The third direction is the front-back direction.

It should also be noted that when the flat voice coil 32 is energized, the flat voice coil 32 performs a reciprocating motion of cutting magnetic field lines in the magnetic gap 224, and the diaphragm 31 is driven to vibrate up and down, so that the air is driven to generate acoustic and the energy conversion between electricity and acoustic is completed. The flat voice coil 32 can be directly connected to the diaphragm 31, or the flat voice coil 32 can be connected to the diaphragm 31 through other structural parts such as a connecting frame.

According to an embodiment of the present application, the first magnet 221 can be a single bar magnet or a plurality of segmented magnets; the second magnet 222 can be a single bar magnet or a plurality of segmented magnets; the third magnet 223 can be a single bar magnet or a plurality of segmented magnets.

In the embodiment, the first magnet 221, the second magnet 222 and the third magnet 223 are connected sequentially, so that the entire magnetic circuit system 2 becomes more compact and the space occupied by the magnetic circuit system 2 is reduced. In an embodiment, the third magnet 223 is provided at the support plate 21 to realize the connection between the magnet assembly 22 and the support plate 21. In an embodiment, the magnet assembly 22 can be connected and fixed to the housing 1 by connecting the first magnet 221 to the housing 1.

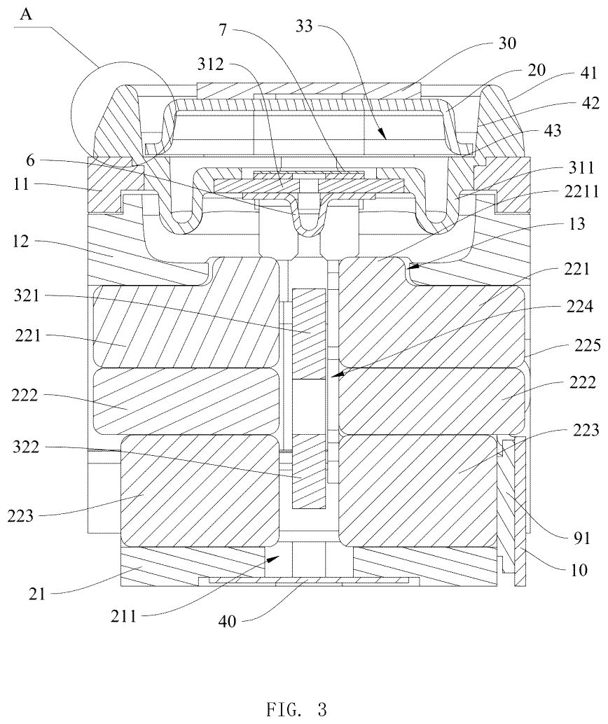

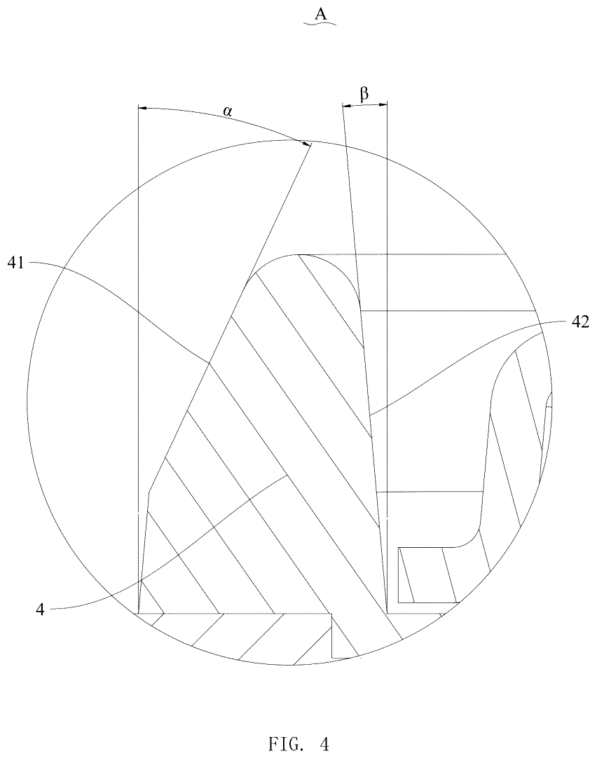

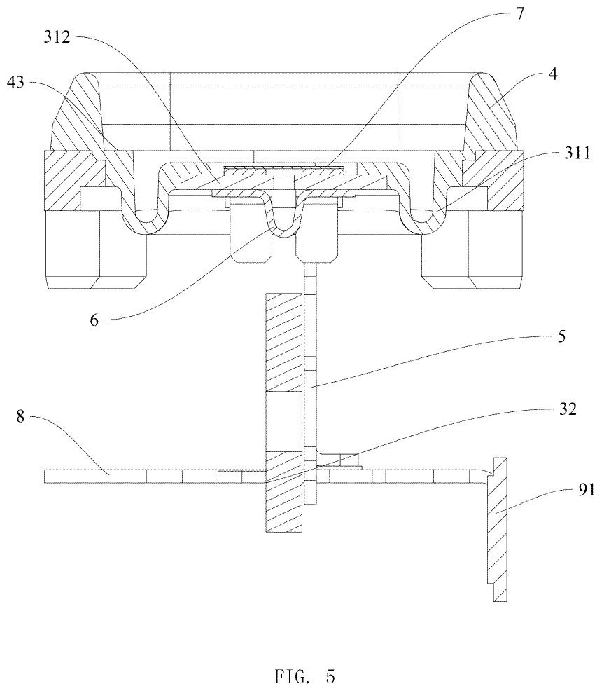

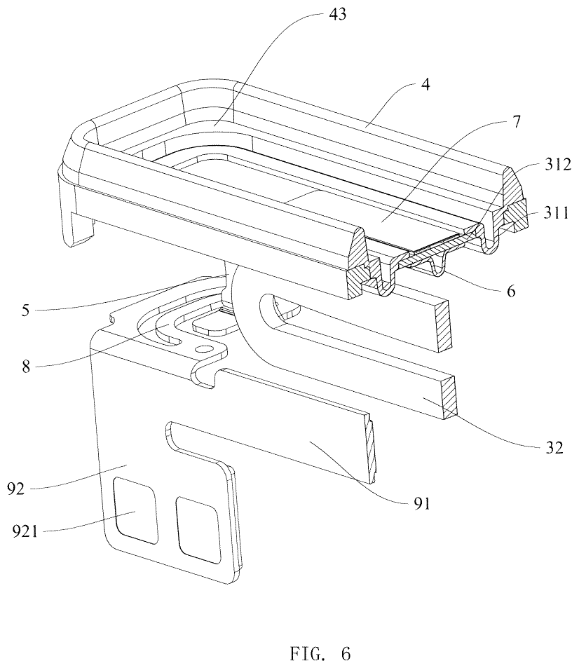

As shown in FIG. 3, FIG. 5 and FIG. 6, in an embodiment, the acoustic transducer 100 further includes a waterproof seal ring 4, the waterproof seal ring 4 is provided around the folded ring 311; the waterproof seal ring 4, the folded ring 311, the reinforcement part 312 and the housing 1 are integrally injection-molded. By providing the waterproof seal ring 4, the waterproof seal ring 4, the folded ring 311, the reinforcement part 312 and the housing 1 are integrally injection-molded, thereby effectively reducing the number of sealing surfaces and improving the waterproof performance of the acoustic transducer 100. It should be noted that the height of the diaphragm 31 is lower than the height of the waterproof seal ring 4, so that a vibration gap 33 is formed between the diaphragm 31 and the waterproof seal ring 4. When the waterproof seal ring 4 is in sealing abutment with the shell 200, the vibration gap 33 provides a large vibration space for the diaphragm 31, thereby reducing the probability of interference between the diaphragm 31 and the shell 200.

As shown in FIG. 3 and FIG. 4, in an embodiment, an outer side wall 12 of the waterproof seal ring 4 is provided with a first inclined surface 41 provided obliquely inwards, an inner side wall 12 of the waterproof seal ring 4 is provided with a second inclined surface 42 provided obliquely outwards, and the included angle between the first inclined surface 41 and the first direction is greater than the included angle between the second inclined surface 42 and the first direction. With the arrangement, when the waterproof seal ring 4 abuts against the shell 200 of the electronic device, the waterproof seal ring 4 is bent inward under compression instead of being folded outward, thereby ensuring that the acoustic transducer 100 has good waterproof performance. As shown in FIG. 4, the included angle between the first inclined surface 41 and the first direction is α, and the included angle between the second inclined surface 42 and the first direction is β.

As shown in FIG. 2, FIG. 5 and FIG. 6, in an embodiment, the vibration system 3 further includes a bracket 5, and the reinforcement part 312 and the flat voice coil 32 are connected to the bracket 5; the driving force of the flat voice coil 32 is transmitted by providing the bracket 5, thereby pushing the diaphragm 31 to vibrate.

In an embodiment, the reinforcement part 312 is provided with a support part extended along the first direction, and the support part is connected to the flat voice coil 32; the flat voice coil 32 is connected to the support part, thereby replacing the connection function realized by the conventional bracket 5, thereby omitting the structural part of the bracket 5, reducing the mounting process of the bracket 5 and lowering the production cost of the acoustic transducer 100. It should be noted that the reinforcement part 312 can be made of a polymer material, such as polyphthalamide, polyphthalamide added with 35% glass fiber material, or carbon fiber, metal alloy and other materials.

As shown in FIG. 8 to FIG. 10, in an embodiment, the vibration system 3 further includes a reinforcement bracket 6, and the reinforcement bracket 6 is provided at a side of the reinforcement part 312 facing the flat voice coil 32; the reinforcement bracket 6 is bent towards the flat voice coil 32 along the first direction to form a reinforcement bent part 64; the ratio of the height of the reinforcement bent part 64 in the first direction to the width of the reinforcement part 312 in the second direction is greater than 1:4; or, the ratio of the height of the reinforcement bent part 64 in the first direction to the width of the reinforcement part 312 in the second direction is not less than 1:10 and not greater than 1:4. The ratio of the height of the reinforcement bent part 64 in the first direction to the width of the reinforcement part 312 in the second direction is greater than 1:4, and the arrangement can make the split vibration frequency of the reinforcement part 312 be after 10 kHz. The ratio of the height of the reinforcement bent part 64 in the first direction to the width of the reinforcement part 312 in the second direction is not less than 1:10 and not greater than 1:4, and the arrangement can make the split vibration frequency of the reinforcement part 312 be between 4 kHz and 10 kHz. As shown in FIG. 8, the height of the reinforcement bent part 64 in the first direction is a, and the width of the reinforcement part 312 in the second direction is b.

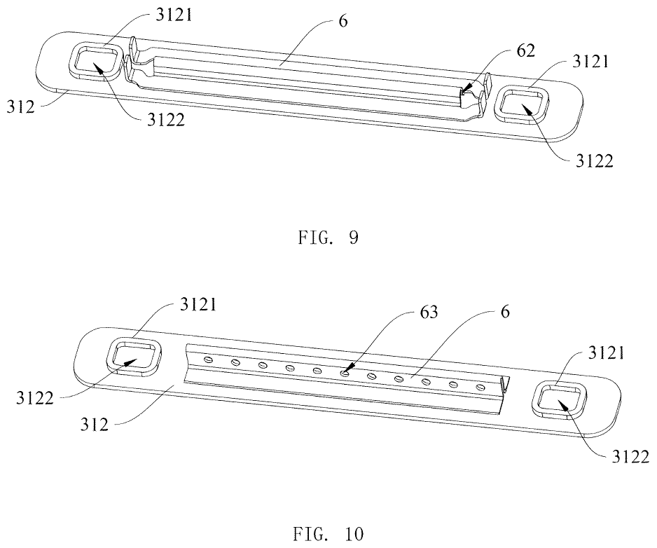

As shown in FIG. 9, according to an embodiment of the present application, the reinforcement bracket 6 is hollow to form a cavity 61, at least one of the two ends of the reinforcement bracket 6 is provided with an opening 62 communicating with the cavity 61, and the cavity 61 is communicated with the micro holes 314 on the reinforcement part 312, so as to balance the internal and external air pressure of the acoustic transducer 100.

As shown in FIG. 10, according to another embodiment of the present application, the reinforcement bracket 6 is hollow to form a cavity 61, and the cavity 61 is communicated with the micro holes 314 on the reinforcement part 312; the outer wall of the reinforcement bracket 6 is provided with a plurality of communicating holes 63 communicated with the cavity 61, and the plurality of communicating holes 63 are provided at intervals sequentially along the extending direction of the reinforcement bracket 6; the internal and external air pressure of the acoustic transducer 100 is balanced by providing the communicating holes 63.

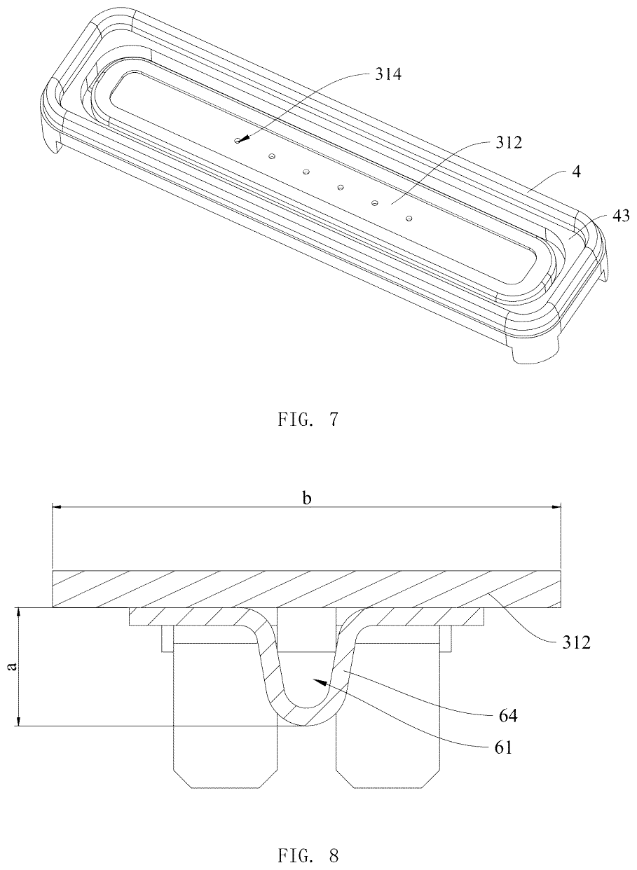

As shown in FIG. 7, in an embodiment, the reinforcement part 312 is provided with a plurality of micro holes 314, and the acoustic transducer 100 further includes a waterproof and breathable film 7 covering the micro holes 314. The arrangement of a plurality of micro holes 314 on the reinforcement part 312 is beneficial to the balance of the internal and external air pressure of the acoustic transducer 100, and the arrangement of the waterproof and breathable film 7 covering the micro holes 314 effectively improves the waterproof performance of the acoustic transducer 100 while ensuring the balance of the internal and external air pressure of the acoustic transducer 100.

In an embodiment, at least a part of the structure of the reinforcement part 312 is made of a breathable material, and the acoustic transducer 100 further includes a waterproof and breathable film 7 covering the breathable material; at least a part of the reinforcement part 312 is made of a breathable material, which is beneficial to the balance of the internal and external air pressure of the acoustic transducer 100, and the arrangement of the waterproof and breathable film 7 covering the breathable material effectively improves the waterproof performance of the acoustic transducer 100 while ensuring the balance of the internal and external air pressure of the acoustic transducer 100. It should be noted that the breathable material can be organic aerogel, foam metal, etc.

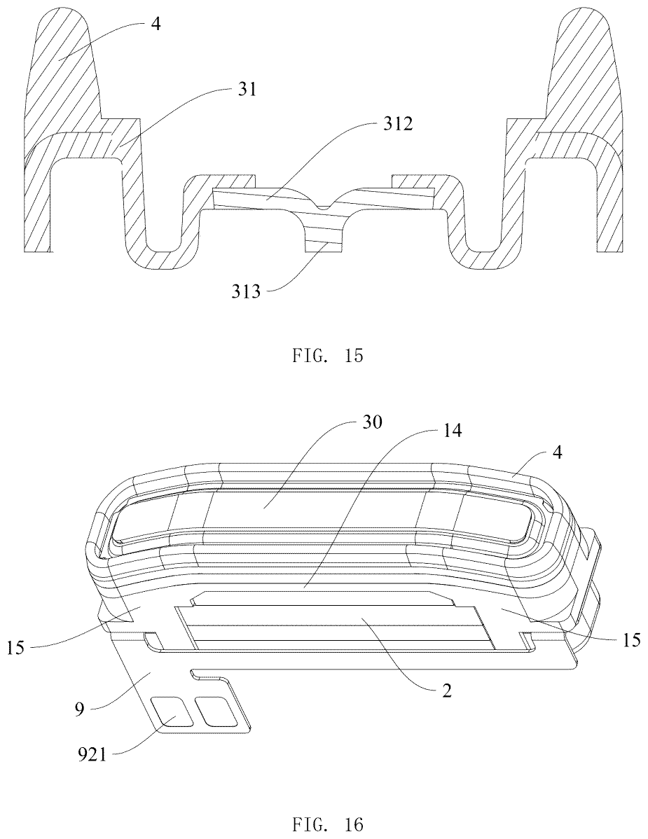

As shown in FIG. 15, in an embodiment, the reinforcement part 312 is provided with reinforcing ribs 313, and the reinforcing ribs 313 are located in the central area of the reinforcement part 312 and extend along the long side direction of the housing 1. The structure of the reinforcement part 312 is strengthened by providing the reinforcing ribs 313, so that the resonance of the reinforcement part 312 can be effectively shifted to high frequency.

As shown in FIG. 1 and FIG. 3, in an embodiment, the housing 1 includes an annular main body 11 and a side wall 12 connected to the annular main body 11, the side wall 12 is provided with a first through hole 121, and each magnet assembly 22 is provided with a first protruding part 225 extending into the first through hole 121; the first through hole 121 is opened on the side wall 12, so that each magnet assembly 22 can extend outwards to form the first protruding part 225, thereby increasing the volume of the magnet assembly 22, improving the magnetic field strength and further enhancing the acoustic performance of the acoustic transducer 100. It should be noted that the first through hole 121 extends through the two side walls 12 provided oppositely along the second direction, and the two outer walls of each magnet assembly 22 provided oppositely along the second direction. Each magnet assembly 22 is provided with two outer walls, the two outer walls are oppositely provided along the second direction. Each outer wall extends outwards to form the first protruding part 225, and one of the two first protruding parts 225 is located in one of the two first through holes 121, and another of the two first protruding parts 225 is located in another of the two first through holes 121.

As shown in FIG. 3 and FIG. 11, in an embodiment, a side of the first magnet 221 adjacent to the magnetic gap 224 protrudes distant from the support plate 21 along the first direction to form a second protruding part 2211, the housing 1 is provided with a second through hole 13 configured to avoid the second protruding part 2211, and the second through hole 13 is communicated with the magnetic gap 224. The size of the first magnet 221 is expanded by providing the second protruding part 2211, the magnetic field area of the flat voice coil 32 is further expanded, and the driving factor of the flat voice coil 32 can be symmetrical relative to the static equilibrium position.

As shown in FIG. 1, FIG. 2 and FIG. 6, in an embodiment, the acoustic transducer 100 further includes a centering plate 8, the centering plate 8 includes a first fixation part 81, an elastic arm part 83 and a second fixation part 82, the first fixation part 81 is provided at the housing 1, the second fixation part 82 is connected to the flat voice coil 32, and one end of the elastic arm part 83 is connected to the first fixation part 81 and another end of the elastic arm part 83 is connected to the second fixation part 82. Each magnet assembly 22 is provided with an avoiding space configured to avoid the centering plate 8. The probability of polarization of the flat voice coil 32 is reduced and the vibration stability of the flat voice coil 32 is improved by providing the centering plate 8. In the embodiment, a mounting space for the centering plate 8 is formed between the magnet assemblies 22.

In an embodiment, two centering plates 8 are provided. One of the two centering plates 8 is provided at one end of the housing 1 along the long side direction, and the other of the two centering plates 8 is provided at another end of the housing 1 along the long side direction; the two centering plates 8 are connected by a conductive connecting part 9, and the conductive connecting part 9 is provided with an external welding pad 921 electrically connected to an external circuit. The conductive connecting part 9 is provided along the long side of the housing 1, so that the two centering plates 8 can be electrically conducted, thereby facilitating the introduction of external circuit current into the flat voice coil 32.

As shown in FIG. 2 and FIG. 14, in an embodiment, the housing 1 includes an annular main body 11 and a side wall 12 connected to the annular main body 11, the support plate 21 includes a bottom plate 212 and a coaming 213, the magnet assembly 22 is provided at the bottom plate 212, the coaming 213 is connected to the side wall 12, and the first fixation part 81 is clamped between the coaming 213 and the side wall 12. The first fixation part 81 is sandwiched between the coaming 213 and the side wall 12, thereby effectively fixing the first fixation part 81 and improving the vibration stability of the flat voice coil 32.

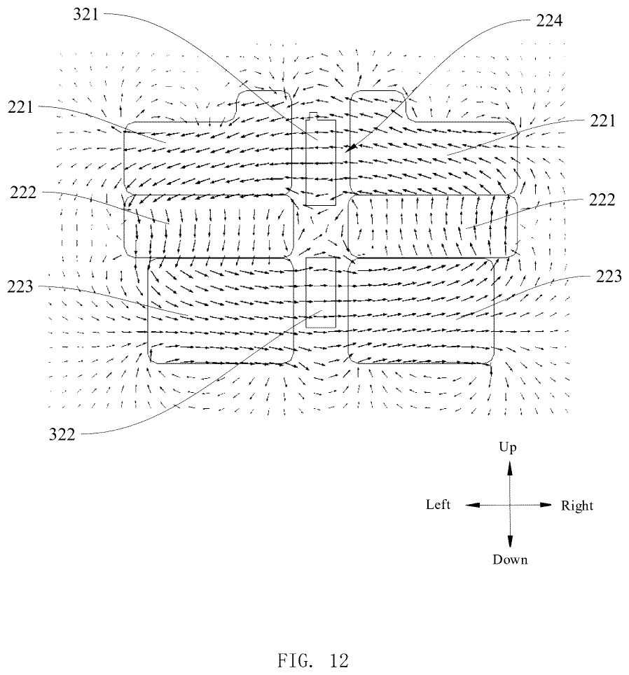

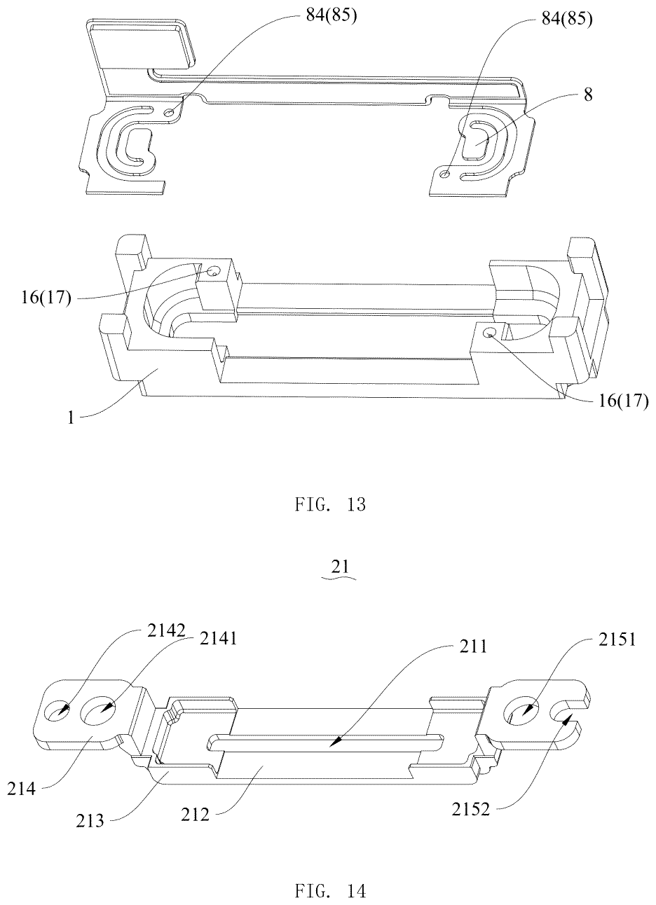

As shown in FIG. 2 and FIG. 13, in an embodiment, the first fixation part 81 is provided with a glue injection hole 84, the housing 1 is provided with a glue injection groove 16 communicated with the glue injection hole 84, and the glue injection groove 16 is configured to contain glue; glue is injected into the glue injection groove 16 through the glue injection hole 84, so that the first fixation part 81 is connected to the housing 1 through solidified glue, thereby improving the reliability of the connection between the first fixation part 81 and the housing 1.

As shown in FIG. 2 and FIG. 13, in an embodiment, the first fixation part 81 is provided with a first welding pad 85, the housing 1 is provided with a second welding pad 17 welded with the first welding pad 85; the reliability of the connection between the first fixation part 81 and the housing 1 is improved by welding the first welding pad 85 and the second welding pad 17.

As shown in FIG. 2 and FIG. 6, in an embodiment, the vibration system 3 further includes a bracket 5, the bracket 5 including a main body part 51, a first connecting part 52, a second connecting part 53, a third connecting part 54, and the main body part 51 extends along the first direction, the first connecting part 52 is located at one end of the main body part 51 along the first direction, the second connecting part 53 is located at another end of the main body part 51 along the first direction. and the first connecting part 52 and the first connecting part 52 are bent along the second direction, and the third connecting part 54 extends from an inner edge of the main body part 51 along the first direction, the first connecting part 52 is connected to the reinforcement part 312, the second connecting part 53 is connected to the second fixation part 82, and the third connecting part 54 is connected to a side surface of the flat voice coil 32. The arrangement enables the bracket 5 to connect the diaphragm 31, the flat voice coil 32 and the centering plate 8, thereby simplifying the connection mode of each component of the vibration system 3, saving the arrangement of parts, reducing the occupation of the space of the acoustic transducer 100 and improving the acoustic performance of the acoustic transducer 100. It should be noted that two brackets 5 are provided, and one of the two brackets 5 is provided at one end of the flat voice coil 32 along the third direction, and another of the two brackets 5 is provided at another end of the flat voice coil 32 along the third direction thereby effectively reducing the probability of polarization of the flat voice coil 32.

As shown in FIG. 2, FIG. 9 and FIG. 10, according to an embodiment of the present application, a side of the reinforcement part 312 facing the magnet assembly 22 is provided with an annular positioning part 3121, a positioning groove 3122 is formed in the middle of the annular positioning part 3121, and the first connecting part 52 extends into the first positioning groove 3122 and is connected to the reinforcement part 312. The assembly of the bracket 5 is facilitated by providing the annular positioning part 3121. The number of the annular positioning parts 3121 is equal to the number of the brackets 5 and the annular positioning parts 3121 and the brackets 5 are provided in a one-to-one correspondence.

In an embodiment, the conductive connecting part 9 and the centering plate 8 are an integrally molded part; the conductive connecting part 9 and the centering plate 8 are integrally molded, thereby reducing the number of parts to be assembled and omitting the assembly steps, which not only improves the assembly efficiency of the acoustic transducer 100 but also avoids assembly errors.

In an embodiment, the conductive connecting part 9 includes a main body part 91 and an external connecting part 92, the main body part 91 is connected to the two centering plates 8, and the external connecting part 92 is connected to one end of the main body part 91, the external connecting part 92 is provided with the external welding pad 921, the main body part 91 is provided at a side surface of the magnetic circuit system 2, and an outer surface of the main body part 91 is within a range of an outer surface of the housing. The outer surface of the main body part 91 is within the range of the outer surface of the housing 1, thereby avoiding the increase of the overall size of the acoustic transducer 100 caused by the protrusion of the main body part 91 and the risk of interference between the main body part 91 and other components of the electronic device.

As shown in FIG. 2 and FIG. 3, in an embodiment, the conductive connecting part 9 includes a main body part 91 and an external connecting part 92, the main body part 91 is connected to the two centering plates 8, and the external connecting part 92 is connected to one end of the main body part 91, the external connecting part 92 is provided with the external welding pad 921, the main body part 91 is provided at a side surface of the magnetic circuit system 2, the acoustic transducer 100 further includes a pressing plate 10, the pressing plate 10 is connected to the housing 1, the main body part 91 is provided between the third magnet 223 and the pressing plate 10, and an outer surface of the pressing plate 10 is within a range of the an outer surface of the housing 1. The pressing plate 10 is provided to prevent the main body part 91 from warping and interfering with other parts, and the outer surface of the pressing plate 10 does not exceed the outer surface of the housing 1 to avoid the increase of the overall size of the acoustic transducer 100 caused by the protrusion of the pressing plate 10 from the outer surface of the housing 1 and the interference of the pressing plate 10 protruding from the outer surface of the housing 1 with other parts. It should be noted that the pressing plate 10 is provided with a riveting hole, the riveting hole can be fixedly connected to a hot-melt rivet provided at the housing 1.

As shown in FIG. 2, FIG. 3 and FIG. 17, in an embodiment, the acoustic transducer 100 further includes a front cover 20, the front cover 20 is provided at a side of the diaphragm 31 distant from the magnetic circuit system 2, the front cover 20 is provided with mesh holes 201, and the acoustic transducer 100 further includes a dustproof net 30, the dustproof net 30 covers the mesh holes 201. The probability of the failure of the acoustic transducer 100 caused by the diaphragm 31 being punctured by sharp objects is effectively reduced by providing the mesh holes 201 on the front cover 20. The dustproof net 30 is provided to cover the mesh holes 201, so as to prevent external dust from falling on the diaphragm 31 through the mesh holes 201 and avoid affecting the acoustic performance of the acoustic transducer 100. It should be noted that a plurality of the mesh holes 201 are provided, the shapes and sizes of the plurality of mesh holes 201 are not completely the same, and the distribution of the plurality of mesh holes 201 can be adjusted according to actual requirements.

As shown in FIG. 2 and FIG. 3, in an embodiment, the acoustic transducer 100 further includes a waterproof seal ring 4, the waterproof seal ring 4 is connected to a side of the housing 1 distant from the magnetic circuit system 2, the waterproof seal ring 4 surrounds the folded ring 311 and forms an annular step 43 at a joint of waterproof seal ring 4 and the folded ring 311, the front cover 20 is provided at the annular step 43 and located inside the waterproof seal ring 4; the front cover 20 is reliably supported by forming the annular step 43, and the front cover 20 is placed at the annular step 43, so that the front cover 20 does not protrude from the waterproof seal ring 4 to cause an increase in the overall size of the acoustic transducer 100. Providing the front cover 20 on the annular step 43 and inside the waterproof seal ring 4 effectively reduces the size of the acoustic transducer 100, so that the acoustic transducer 100 can better adapt to the requirements of narrow mounting environments.

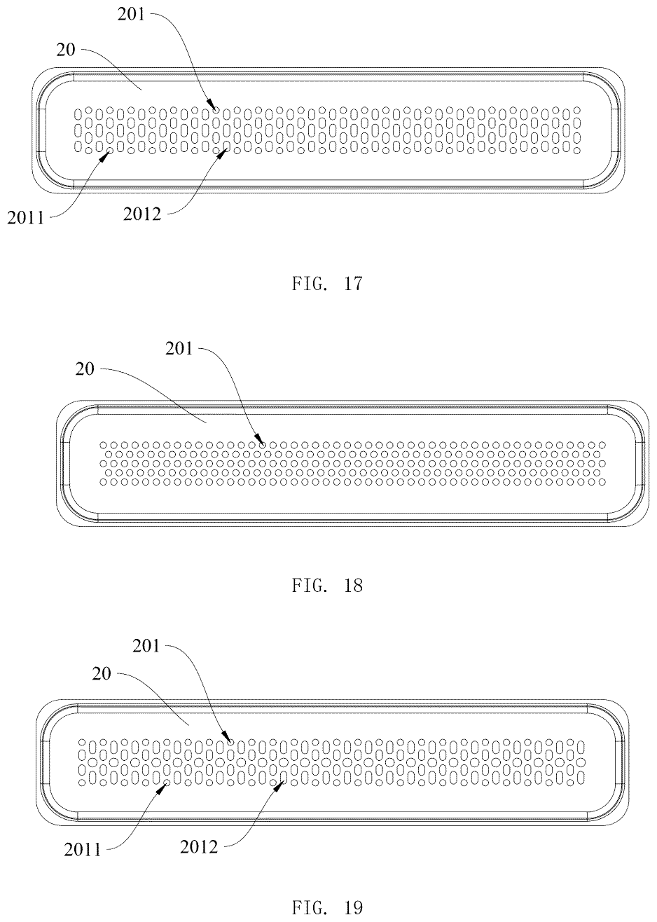

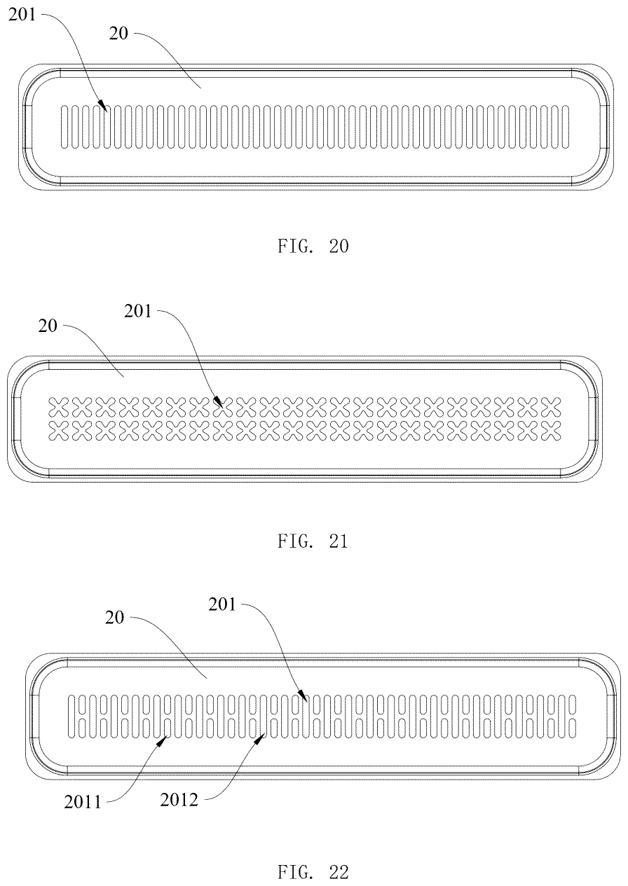

As shown in FIG. 17 to FIG. 22, in an embodiment, the mesh holes 201 are of an irregular shape; the amplitude symmetry of the acoustic transducer 100 can be adjusted by adjusting the shape of the mesh holes 201.

In an embodiment, the mesh holes 201 include first holes 2011 and second holes 2012, and the hole areas of the first holes 2011 and the second holes 2012 are different; the first holes 2011 and the second holes 2012 are staggered along the long side or the short side of the acoustic transducer 100, or the first holes 2011 are scattered between the second holes 2012, or the front cover 20 includes a first area corresponding to the first holes 2011 and a second area corresponding to the second holes 2012. The amplitude symmetry of the acoustic transducer 100 can also be effectively adjusted by changing the arrangement mode of the first holes 2011 and the second holes 2012.

As shown in FIG. 3 and FIG. 11, in an embodiment, the flat voice coil 32 includes a first long-axis section 321 and a second long-axis section 322, and the first long-axis section 321 and the second long-axis section 322 are provided at intervals sequentially along the first direction. The first long-axis section 321 is connected to the diaphragm 31, and the first long-axis section 321 and the second long-axis section 322 extend along a third direction. The first direction, the second direction and the third direction are mutually orthogonal. The thickness of the first magnet 221 along the first direction is not less than 80 percent of the height of the first long-axis section 321 along the first direction; the arrangement increases the number of magnetic field lines passing through the first long-axis section 321, thereby improving the driving force of the flat voice coil 32 and enhancing the acoustic performance of the acoustic transducer 100.

In an embodiment, the thickness of the third magnet 223 along the first direction is not less than 80 percent of the height of the second long-axis section 322 along the first direction; the arrangement increases the number of magnetic field lines passing through the second long-axis section 322, thereby improving the driving force of the flat voice coil 32 and enhancing the acoustic performance of the acoustic transducer 100.

In an embodiment, the thicknesses of the first magnet 221 and the third magnet 223 along the first direction are greater than the thickness of the second magnet 222 along the first direction. The arrangement increases the number of magnetic field lines passing through the first long-axis section 321 and the second long-axis section 322, thereby improving the driving force of the flat voice coil 32 and enhancing the acoustic performance of the acoustic transducer 100.

In an embodiment, the aspect ratio of the inner diameter of the flat voice coil 32 is not greater than 20:1; the aspect ratio of the inner diameter of the flat voice coil 32 is controlled to be not greater than 20:1 to facilitate the winding of the flat voice coil 32. It should be noted that the aspect ratio of the inner diameter of the flat voice coil 32 refers to the ratio of the length of the inner ring of the flat voice coil 32 along the third direction to the width of the inner ring of the flat voice coil 32 along the first direction.

In an embodiment, the aspect ratio of the acoustic transducer 100 is not greater than 10:1, so as to better adapt to the mounting requirements of some existing narrow mounting environments.

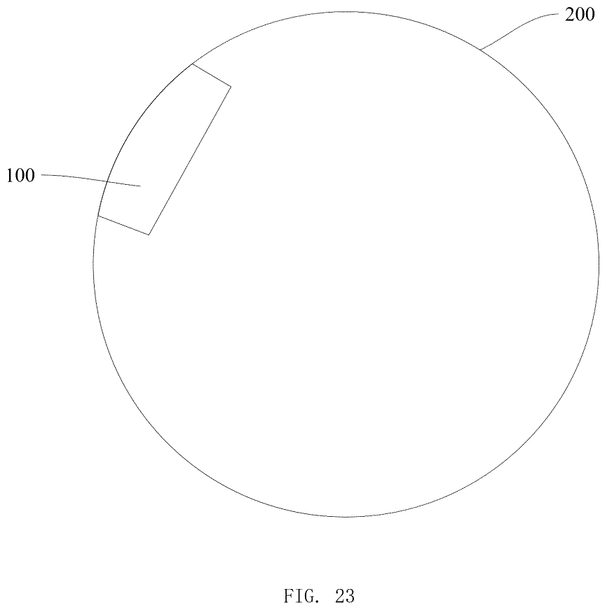

As shown in FIG. 16 and FIG. 23, in an embodiment, the housing 1 is provided with a central part 14 and two end parts 15; one of the two end parts 15 is located at one end of the central part 14 along the long side direction of the housing 1, and the other one of the two end parts 15 is located at the other end of the central part 14 along the long side direction of the housing 1; and an outer surface of the central part 14 protrudes towards a side distant from the flat voice coil 32. It should be noted that the outer surface of the central part 14 adjacent to the diaphragm 31 protrudes distant from the flat voice coil 32, the central part 14 protrudes distant from the flat voice coil 32 to better adapt to the shape of the shell 200 of the electronic device, so that the housing 1 can extend along the shell 200 to realize the sealing abutment between the housing 1 and the shell 200; the central part 14 protrudes distant from the flat voice coil 32, so that the housing 1 is in a curved shape or an approximately curved shape to adapt to the shape of the shell 200, thereby improving the utilization rate of the internal space of the shell 200. In the embodiment, the shape of the diaphragm 31 is similar to the shape of the housing 1. By adapting the shape of the housing 1 to the shape of the shell 200, a part of the gap is used as the vibration space of the diaphragm 31, so that the vibration space of the diaphragm 31 is increased without increasing the mounting space of the acoustic transducer 100, and the volume of the front acoustic cavity of the acoustic transducer 100 is also increased, thereby effectively improving the acoustic performance of the acoustic transducer 100. It should be noted that the outer surface of the housing 1 can be an arc structure as a whole, or the central part 14 can be a flat part and the end parts 15 can be flat parts or curved parts, or the central part 14 can be a curved part and the end parts 15 can be flat parts or curved parts.

As shown in FIG. 2 and FIG. 3, in an embodiment, the support plate 21 is provided with an avoiding groove configured to avoid the flat voice coil 32; the avoiding groove is communicated with the magnetic gap 224, and a larger vibration space is provided for the flat voice coil 32 by providing the avoiding groove.

In an embodiment, the support plate 21 is provided with an avoiding hole 211 configured to avoid the flat voice coil 32, the acoustic transducer 100 further includes a covering part 40 covering the avoiding hole 211, and the covering part 40 is provided at a side of the support plate 21 distant from the magnet assembly 22 along the first direction; a larger vibration space is provided for the flat voice coil 32 by opening the avoiding hole 211; the covering part 40 covering the avoiding hole 211 is provided to adjust the amplitude symmetry of the acoustic transducer 100. It should be noted that the covering part 40 can be a cover plate or a nylon mesh cloth.

As shown in FIG. 14, in an embodiment, the support plate 21 includes a bottom plate 212, a coaming 213 provided at the periphery of the bottom plate 212, and a first mounting lug 214 and a second mounting lug 215, the first mounting lug 214 is provided at one end of the coaming 213 along the third direction, the second mounting lug 215 is provided at another end of the coaming 213 along the third direction, the first mounting lug 214 is provided with a first mounting hole 2141 and a first positioning hole 2142 at intervals along the third direction, the second mounting lug 215 is provided with a second mounting hole 2151 and a second positioning hole 2152 at intervals along the third direction, the second positioning hole 2152 extends through an outer edge of the second mounting lug 215 along the third direction, and the first direction, the second direction and the third direction are mutually orthogonal. The mounting of the acoustic transducer 100 is facilitated by providing the first mounting hole 2141 and the second mounting hole 2151, and the precise positioning of the acoustic transducer 100 is facilitated by providing the first positioning hole 2142 and the second positioning hole 2152, thereby preventing the acoustic transducer 100 from deflecting during assembly into the shell 200.

As shown in FIG. 23, the present application also provides an electronic device, the electronic device includes a shell 200 and the above-mentioned acoustic transducer 100, the acoustic transducer 100 being provided in the shell 200. The electronic device can be a computer, a mobile phone, an intelligent wearable device, etc. Since the electronic device adopts all the technical solutions of the above embodiments, it at least has all the beneficial effects brought by the technical solutions of the above embodiments, which will not be repeated here.

The above are only exemplary embodiments of the present application, and do not limit the patent scope of the present application. Any equivalent structural transformations made by using the contents of the specification and drawings of the present application under the technical concept of the present application, or direct/indirect applications in other related technical fields are all included in the patent protection scope of the present application.

What is claimed is:

1. An acoustic transducer, a aspect ratio of the acoustic transducer being greater than 2:1, comprising:
a housing;
a magnetic circuit system; and
a vibration system,
wherein the magnetic circuit system comprises a support plate and two magnet assemblies provided at the support plate at intervals, and a magnetic gap is formed between the two magnet assemblies; the support plate is made of a non-magnetic material, and each magnet assembly comprises a first magnet, a second magnet and a third magnet provided sequentially along a first direction; the third magnet is provided at the support plate, and the first magnet and the third magnet are magnetized along a second direction; magnetization directions of the first magnet and the third magnet are opposite, and the first direction is perpendicular to the second direction;
the second magnet is magnetized along the first direction, and a polarity of a magnetic pole of the second magnet facing the first magnet is the same as a polarity of a magnetic pole of the first magnet adjacent to the magnetic gap, to make each magnet assembly form a magnetic field enhancement side facing the magnetic gap; the polarities of the magnetic poles of the two first magnets adjacent to the magnetic gap are opposite; and
the vibration system comprises a diaphragm and a flat voice coil configured to drive the diaphragm to vibrate along the first direction, and the diaphragm comprises a folded ring and a reinforcement part provided in a central area of the folded ring; the folded ring is connected to the housing, and the flat voice coil is connected to the reinforcement part and located in the magnetic gap; and an axial direction of the flat voice coil is provided along the second direction.

2. The acoustic transducer according to claim 1, further comprising:
a waterproof seal ring,
wherein the waterproof seal ring is provided around the folded ring; the waterproof seal ring, the folded ring, the reinforcement part and the housing are integrally injection-molded; or
an outer side wall of the waterproof seal ring is provided with a first inclined surface provided obliquely inwards; an inner side wall of the waterproof seal ring is provided with a second inclined surface provided obliquely outwards; and an included angle between the first inclined surface and the first direction is greater than an included angle between the second inclined surface and the first direction.

3. The acoustic transducer according to claim 1, wherein the vibration system further comprises a bracket, and the reinforcement part and the flat voice coil are connected to the bracket; or
the reinforcement part is provided with a bent support part extended along the first direction, and the support part is connected to the flat voice coil; and/or
the vibration system further comprises a reinforcement bracket; the reinforcement bracket is provided at a side of the reinforcement part facing the flat voice coil, and the reinforcement bracket is bent towards the flat voice coil along the first direction to form a reinforcement bent part; a ratio of a height of the reinforcement bent part in the first direction to a width of the reinforcement part in the second direction is greater than 1:4; or
the ratio of the height of the reinforcement bent part in the first direction to the width of the reinforcement part in the second direction is not less than 1:10, and not greater than 1:4.

4. The acoustic transducer according to claim 1, wherein the reinforcement part is provided with a plurality of micro holes, and the acoustic transducer further comprises a waterproof and breathable film covering the micro holes; or
at least a part of a structure of the reinforcement part is made of a breathable material, and the acoustic transducer further comprises a waterproof and breathable film covering the breathable material; and/or
the reinforcement part is provided with reinforcing ribs, and the reinforcing ribs are located in a central area of the reinforcement part and extend along a long side direction of the housing.

5. The acoustic transducer according to claim 1, wherein the housing comprises an annular main body and a side wall connected to the annular main body; the side wall is provided with a first through hole, and the magnet assembly is provided with a first protruding part extending into the first through hole; and/or
a side of the first magnet adjacent to the magnetic gap protrudes distant from the support plate along the first direction to form a second protruding part; the housing is provided with a second through hole configured to avoid the second protruding part, and the second through hole is communicated with the magnetic gap.

6. The acoustic transducer according to claim 1, further comprising:
a centering plate,
wherein the centering plate comprises a first fixation part, an elastic arm part and a second fixation part; the first fixation part is provided at the housing, and the second fixation part is connected to the flat voice coil; one end of the elastic arm part is connected to the first fixation part, and the other end of the elastic arm part is connected to the second fixation part.

7. The acoustic transducer according to claim 6, wherein two centering plates are provided; one of the two centering plates is provided at one end of the housing along a long side direction, and the other of the two centering plates is provided at the other end of the housing along the long side direction; the two centering plates are connected by a conductive connecting part, and the conductive connecting part is provided with an external welding pad electrically connected to an external circuit.

8. The acoustic transducer according to claim 6, wherein the housing comprises an annular main body and a side wall connected to the annular main body, and the support plate comprises a bottom plate and a coaming; the magnet assembly is provided at the bottom plate, and the coaming is connected to the side wall; and the first fixation part is clamped between the coaming and the side wall; and/or
the first fixation part is provided with a glue injection hole, and the housing is provided with a glue injection groove communicated with the glue injection hole; and the glue injection groove is configured to contain glue; and/or
the first fixation part is provided with a first welding pad, and the housing is provided with a second welding pad welded with the first welding pad; and/or
the vibration system further comprises a bracket; the bracket comprises a main body part, a first connecting part, a second connecting part, and a third connecting part; the main body part extends along the first direction; the first connecting part is located at one end of the main body part along the first direction, and the second connecting part is located at the other end of the main body part along the first direction; the first connecting part and the second connecting part are bent along the second direction, and the third connecting part extends from an inner edge of the main body part along the first direction; the first connecting part is connected to the reinforcement part; the second connecting part is connected to the second fixation part; and
the third connecting part is connected to a side surface of the flat voice coil.

9. The acoustic transducer according to claim 7, wherein the conductive connecting part and the centering plate are an integrally molded part; the conductive connecting part comprises a main body part and an external connecting part; the main body part is connected to the two centering plates, and the external connecting part is connected to one end of the main body part; the external connecting part is provided with the external welding pad, and the main body part is provided at a side surface of the magnetic circuit system; and/or
an outer surface of the main body part is within a range of an outer surface of the housing; and/or
the acoustic transducer further comprises a pressing plate, and the pressing plate is connected to the housing; the main body part is provided between the third magnet and the pressing plate, and an outer surface of the pressing plate is within a range of the outer surface of the housing.

10. The acoustic transducer according to claim 1, further comprising:
a front cover; and
a dustproof net,
wherein the front cover is provided at a side of the diaphragm distant from the magnetic circuit system; the front cover is provided with mesh holes, and the dustproof net covers the mesh holes.

11. The acoustic transducer according to claim 10, further comprising:
a waterproof seal ring,
wherein the waterproof seal ring is connected to a side of the housing distant from the magnetic circuit system, and the waterproof seal ring surrounds the folded ring and forms an annular step at a joint of the waterproof seal ring and the folded ring; the front cover is provided at the annular step and located inside the waterproof seal ring; and/or
the mesh holes are of an irregular shape; and/or
the mesh holes comprise first holes and second holes, and hole areas of the first holes and the second holes are different; the first holes and the second holes are staggered along a long side or a short side of the acoustic transducer, or the first holes are scattered between the second holes, or the front cover comprises a first area corresponding to the first holes and a second area corresponding to the second holes.

12. The acoustic transducer according to claim 1, wherein the flat voice coil comprises a first long-axis section and a second long-axis section, and the first long-axis section and the second long-axis section are provided at intervals sequentially along the first direction; the first long-axis section is connected to the diaphragm, and the first long-axis section and the second long-axis section extend along a third direction; the first direction, the second direction and the third direction are mutually orthogonal;
a thickness of the first magnet along the first direction is not less than 80 percent of a height of the first long-axis section along the first direction; and/or
a thickness of the third magnet along the first direction is not less than 80 percent of a height of the second long-axis section along the first direction; and/or
a thicknesses of the first magnet and the third magnet along the first direction are greater than a thickness of the second magnet along the first direction.

13. The acoustic transducer according to claim 1, wherein an aspect ratio of an inner diameter of the flat voice coil is not greater than 20:1; and/or
the aspect ratio of the acoustic transducer is not greater than 10:1; and/or
the housing comprises a central part and two end parts; one of the two end parts is located at one end of the central part along the long side direction of the housing, and the other one of the two end parts is located at the other end of the central part along the long side direction of the housing; and an outer surface of the central part protrudes towards a side distant from the flat voice coil.

14. The acoustic transducer according to claim 1, wherein the support plate is provided with an avoiding groove configured to avoid the flat voice coil; or
the support plate is provided with an avoiding hole configured to avoid the flat voice coil; the acoustic transducer further comprises a covering part covering the avoiding hole, and the covering part is provided at a side of the support plate distant from the magnet assembly along the first direction; and/or
the support plate comprises a bottom plate, a coaming provided at a periphery of the bottom plate, and a first mounting lug and a second mounting lug; the first mounting lug is provided at one end of the coaming along the third direction, and the second mounting lug is provided at the other end of the coaming along the third direction; the first mounting lug is provided with a first mounting hole and a first positioning hole at intervals along the third direction, and the second mounting lug is provided with a second mounting hole and a second positioning hole at intervals along the third direction; the second positioning hole extends through an outer edge of the second mounting lug along the third direction, and the first direction, the second direction and the third direction are mutually orthogonal.

15. An electronic device, comprising:
a shell; and
the acoustic transducer according to claim 1, wherein the acoustic transducer is provided in the shell.
